(19) United States
(12) Patent Application Publication
(10) Pub. No.: US 2012/0033360 A1
(43) Pub. Date: Feb. 9, 2012

(54) ELECTRONIC DEVICE ASSEMBLY

(75) Inventor: PO-YEN HSU, Tu-Cheng (TW)

(73) Assignee: HON HAI PRECISION INDUSTRY CO., LTD., Tu-Cheng (TW)

(21) Appl. No.: 13/013,748

(22) Filed: Jan. 25, 2011

(30) Foreign Application Priority Data
Aug. 6, 2010 (CN) 201010247297.3

(51) Int. Cl. H05K 7/00

(52) U.S. Cl. 361/679.01

(57) ABSTRACT

An electronic device assembly includes an electronic device and an enclosure receiving the electronic device. The electronic device includes a display and a sensor. The enclosure includes a cover and a controller attached to the cover. The cover is rotatable relative to the electronic device between a first position and a second position. In the first position, the cover covers the electronic device, and the controller controls the sensor transmitting a first signal to the electronic device, for turning off a power supplied to the display. In the second position, the electronic device is exposed, and the controller controls the sensor transmitting a second signal to the electronic device, for turning on the power of the display.

### BACKGROUND

1. Technical Field

The present disclosure relates to electronic device assemblies, more particularly an electronic device assembly, which automatically controls the power supply to a display of the electronic device assembly.

2. Description of Related Art

Nowadays, electronic devices, such as mobile phones, and personal digital assistants, are in high demand. Usually, the electronic device is accommodated in an enclosure for preventing damage. However, the power supplied to the electronic device cannot be automatically turned off when accommodated in the enclosure if the electronic device is not used for some time, so the power is often wasted.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a diagram view of an electronic device assembly in accordance with an embodiment.

FIG. 2 is an exploded, isometric view of an electronic device assembly in accordance with an embodiment.

FIG. 3 is an assembled view of FIG. 2, and shows a cover in a second position.

FIG. 4 is similar to FIG. 3, but shows the cover in another position.

FIG. 5 is similar to FIG. 3, but shows the cover in a first position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

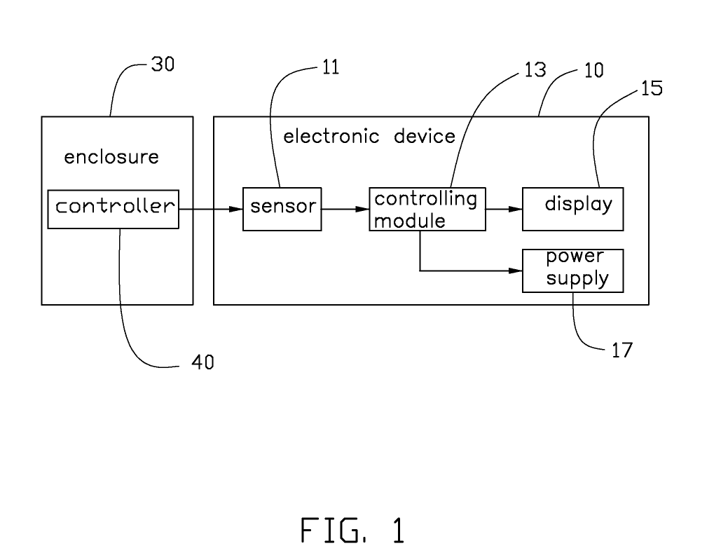

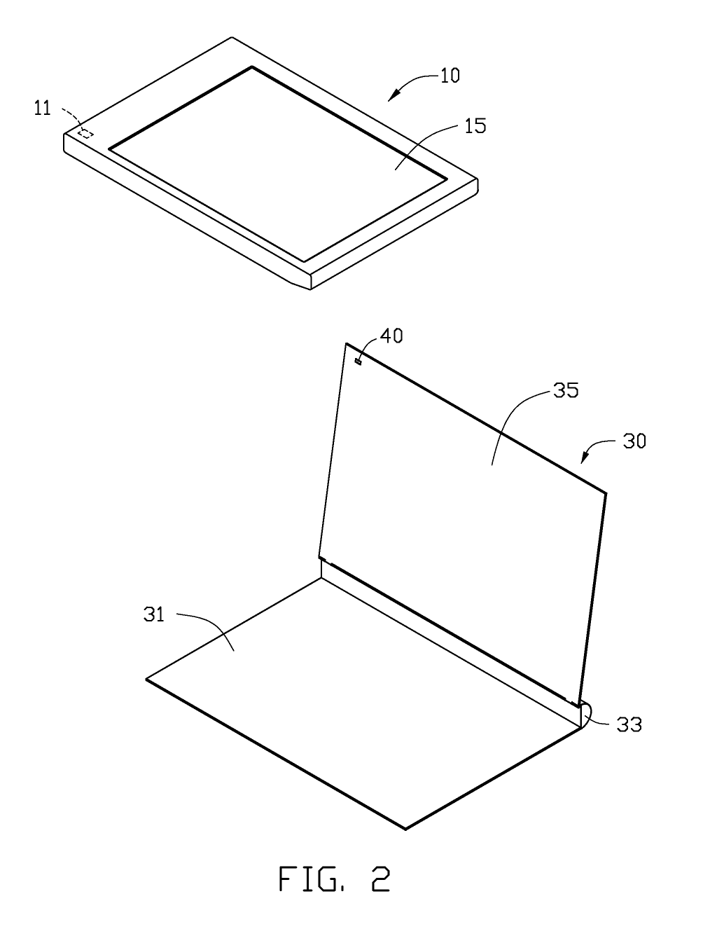

Referring to FIGS. 1 and 2, an electronic device assembly in accordance with an embodiment includes an electronic device 10 and an enclosure 30 configured for receiving the electronic device 10. In one embodiment, the electronic device 10 may be, for example, a mobile phone or a personal digital assistant.

The electronic device 10 includes a display 15 for displaying information and a power supply 17 for supplying power to the electronic device 10. A sensor 11 and a controlling module 13 are disposed in the electronic device 10. The controlling module 13 is electronically connected to the sensor 11. The sensor 11 can transmit signals to the controlling module 13 when in a predetermined magnetic field. In one embodiment, the sensor 11 is secured to a corner of the electronic device 10.

The sensor 11 may be, for example, a reed switch. The reed switch is an electrical switch operated by an applied magnetic field. It consists of a pair of contacts on ferrous metal reeds in a hermetically sealed glass envelope. The contacts may be normally open, closing when a magnetic field is present, or normally closed and opening when a magnetic field is applied. The switch may be actuated by a coil, making a reed relay, or by bringing a magnet near to the switch. Once the magnet is pulled away from the switch, the reed switch will go back to its original position.

The controlling module 13 is used to turn on/off power provided by the power supply 17 to the display 15 and the electronic device 10, when the controlling module 13 is received in the signals from the sensor 11.

The enclosure 30 includes a bottom 31, a connecting portion 33 connected to an edge of the bottom 31, and a cover 35 rotatably connected to the connecting portion 13. In one embodiment, the electronic device 10 is placed on the bottom 31. A controller 40 is attached to the cover 35, corresponding to the sensor 11. The controller 40 can generate a magnetic field. In one embodiment, the controller 40 is a permanent magnet.

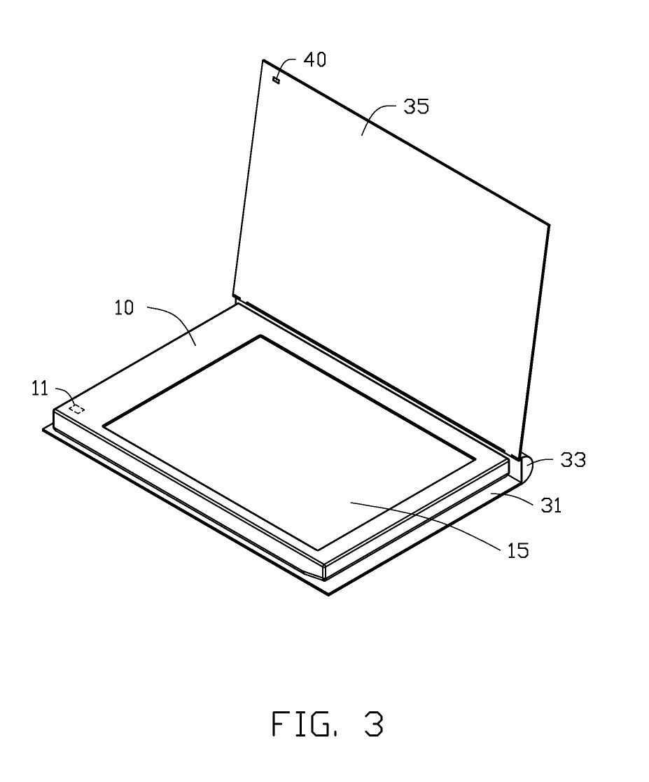

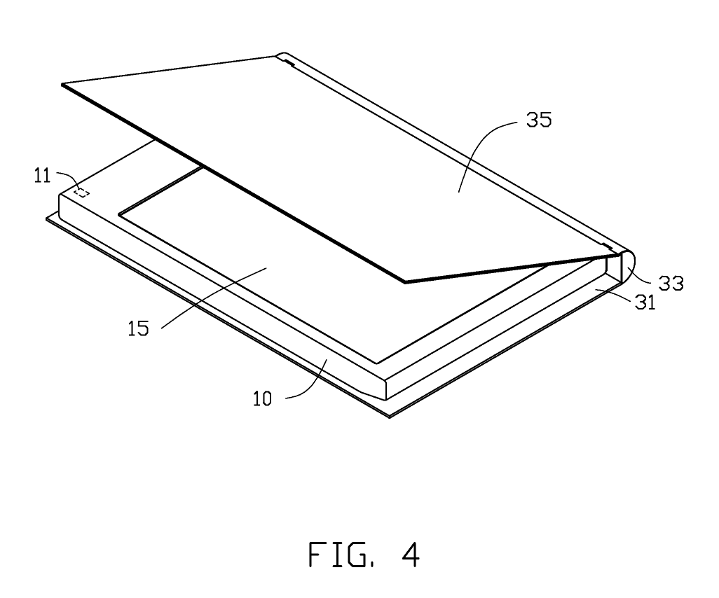

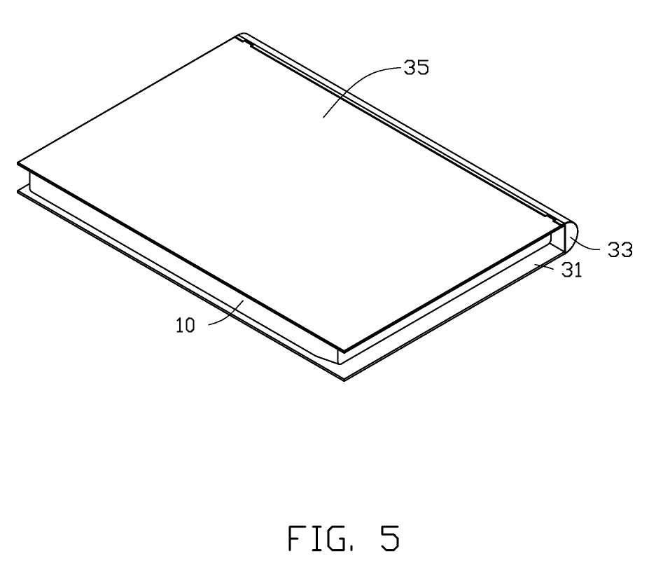

Referring to FIGS. 3-5, the electronic device 10 is placed on the bottom 31, and the cover 35 can be rotated relative to the electronic device 10 between a first position (shown in FIG. 5), and an second position (shown in FIG. 3). In the first position, the cover 35 covers the electronic device 10. The sensor 11 is located below the controller 40 and positioned in an area of the greatest magnetic force of the predetermined magnetic field, which is generated by the controller 40. In the second position, the cover 35 is located such that the electronic device 10 is exposed, the sensor 11 is away from the controller 40 and positioned in a least magnetic force of the predetermined magnetic field.

When the electronic device 10 is not used, the cover 35 is rotated down from the second position to the first position. The sensor 11 is moved in the predetermined magnetic filed from the least magnetic force area to the greatest magnetic force area, and thereby transmitting a first signal to the controlling module 13. The power of the display 15 or the electronic device 10 is turned off when the controlling module 13 receives the first signal.

In use, the cover 35 is rotated up from the first position to the second position, and the sensor 11 is moved away from the predetermined magnetic filed from the greatest magnetic force area to the least magnetic force area. Thereby the sensor 11 transmits a second signal to the controlling module 13. Therefore, the power of the display 15 or the electronic device 10 is turned on when the controlling module 13 receives the second signal.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device assembly comprising:
an electronic device comprising a display and a sensor; and
an enclosure, receiving the electronic device, comprising a cover and a controller attached to the cover;
wherein the cover is rotatable, relative to the electronic device, between a first position, where the cover covers the electronic device, and the controller controls the sensor transmitting a first signal to the electronic device, for turning off a power supplied to the display; and a second position, where the electronic device is exposed, and the controller controls the sensor transmitting a second signal to the electronic device, for turning on the power supplied to the display.

2. The electronic device assembly of claim 1, wherein the electronic device further comprises a controlling module, the controlling module is configured for receiving the first signal, to turn off the power of the display, and receiving the second signal, to turn on the power of the display.

3. The electronic device assembly of claim 2, wherein the controller is configured for generating a magnetic field.

4. The electronic device assembly of claim 3, wherein the sensor is a reed switch.

5. The electronic device assembly of claim 3, wherein the controller is a magnet.

6. The electronic device assembly of claim 1, wherein the enclosure further comprises a bottom, the cover is rotatable relative to the bottom, and the electronic device is located on the bottom.

7. The electronic device assembly of claim 6, wherein the enclosure further comprises a connecting portion, the connecting portion is located on the bottom, and the cover is rotatably located on the connecting portion.

8. The electronic device assembly of claim 1, wherein the sensor is arranged in a corner of the electronic device.

9. An electronic device assembly comprising:
an electronic device comprising a display, a sensor, and a controlling module controlled by the sensor; and
an enclosure, receiving the electronic device, comprising a bottom, a cover rotatably connected to the bottom, and a controller attached to the cover;
wherein the controller is configured for generating a magnetic field for the sensor, and the sensor is configured for transmitting a first signal to the controlling module when in presence of a sufficient magnetic force area, for the controlling module turning off a power supplied to the display, and transmitting a second signal to the controlling module when in presence of an insufficient magnetic force area, for the controlling module turning on the power supplied to the display.

10. The electronic device assembly of claim 9, wherein the sensor is a reed switch.

11. The electronic device assembly of claim 9, wherein the controller is a magnet.

12. The electronic device assembly of claim 9, wherein the enclosure further comprises a connecting portion, and the connecting portion is rotatably located between the bottom and the cover.

13. The electronic device assembly of claim 9, wherein the sensor is arranged in a corner of the electronic device.
